(19) United States
(12) Patent Application Publication
(10) Pub. No.: US 2024/0337934 A1
(43) Pub. Date: Oct. 10, 2024

(54) PHOTOSENSITIVE RESIN COMPOSITION, PHOTOSENSITIVE ELEMENT, PRINTED WIRING BOARD, AND METHOD FOR PRODUCING PRINTED WIRING BOARD

(71) Applicant: Resonac Corporation, Tokyo (JP)

(72) Inventors: Naoki YAMASHITA, Tokyo (JP); Hayato SAWAMOTO, Tokyo (JP); Kaho YAMAGUCHI, Tokyo (JP); Yasuyuki OYAMA, Tokyo (JP); Arisa YAMAKAWA, Tokyo (JP)

(21) Appl. No.: 18/291,075

(22) PCT Filed: Dec. 22, 2021
(86) PCT No.: PCT/JP2021/047629

§ 371 Date: Jan. 22, 2024

(51) Int. Cl. G03F 7/033; G03F 7/105; G03F 7/115; H05K 3/00; H05K 3/28

(52) U.S. Cl. CPC G03F 7/033; G03F 7/105; G03F 7/115; H05K 3/0082; H05K 3/287

(57) ABSTRACT

The present disclosure relates to a photosensitive resin composition for a permanent resist, the photosensitive resin composition including: (A) an acid-modified vinyl group-containing resin; (B) a photopolymerization initiator; and (C) a photopolymerizable compound, in which the photopolymerizable compound includes a photopolymerizable compound having four or more ethylenically unsaturated groups and a photopolymerizable compound having three or fewer ethylenically unsaturated groups.

### TECHNICAL FIELD

The present disclosure relates to a photosensitive resin composition for a permanent resist, a photosensitive element, a printed wiring board, and a method for producing a printed wiring board.

### BACKGROUND ART

Along with performance improvement of various electronic devices, semiconductors are becoming more highly integrated. Accordingly, permanent resists (solder resists) formed on printed wiring boards, semiconductor package substrates, and the like are required to have various performances.

As a photosensitive resin composition used for forming a permanent resist, for example, a photocurable resin composition containing an acid-modified vinyl group-containing epoxy resin, an elastomer, a photopolymerization initiator, a diluent, and a curing agent as essential components is known (see Patent Literature 1).

### CITATION LIST

### Patent Literature

Patent Literature 1: JP H11-240930 A

### SUMMARY OF INVENTION

### Technical Problem

As the wiring pitch of semiconductor package substrates is becoming narrower due to higher integration of semiconductor elements, photosensitive resin compositions used for forming permanent resists are required to have higher resolution.

An object of the present disclosure is to provide a photosensitive resin composition having excellent resolution, a photosensitive element produced using the photosensitive resin composition, a printed wiring board, and a method for producing a printed wiring board.

### Solution to Problem

An aspect of the present disclosure relates to a photosensitive resin composition for a permanent resist, the photosensitive resin composition containing (A) an acid-modified vinyl group-containing resin, (B) a photopolymerization initiator, and (C) a photopolymerizable compound, in which the photopolymerizable compound includes a photopolymerizable compound having four or more ethylenically unsaturated groups and a photopolymerizable compound having three or fewer ethylenically unsaturated groups.

Another aspect of the present disclosure relates to a photosensitive element including a support film and a photosensitive layer formed on the support film, in which the photosensitive layer includes the above-mentioned photosensitive resin composition.

Another aspect of the present disclosure relates to a printed wiring board including a permanent resist including a cured product of the above-mentioned photosensitive resin composition.

Another aspect of the present disclosure relates to a method for producing a printed wiring board, the method including a step of forming a photosensitive layer on a substrate by using the above-mentioned photosensitive resin composition or the above-mentioned photosensitive element; a step of subjecting the photosensitive layer to exposure and development to form a resist pattern; and a step of curing the resist pattern to form a permanent resist.

### Advantageous Effects of Invention

According to the present disclosure, a photosensitive resin composition having excellent resolution, a photosensitive element produced using the photosensitive resin composition, a printed wiring board, and a method for producing a printed wiring board can be provided.

### BRIEF DESCRIPTION OF DRAWINGS

FIG. 1 is a cross-sectional view schematically illustrating a photosensitive element according to the present embodiment.

### DESCRIPTION OF EMBODIMENTS

The present disclosure will be described in detail below. In the present specification, the term “step” includes not only an independent step but also a step that cannot be clearly distinguished from other steps as long as an intended operation of the step is achieved. The term “layer” includes, when observed in a plan view, a structure having a shape that is formed over the entire surface, as well as a structure having a shape that is formed in a portion. A numerical value range indicated using the term “to” indicates a range including the numerical values described before and after the term “to” as the minimum value and the maximum value, respectively. With regard to a numerical value range described stepwise in the present specification, the upper limit value or lower limit value of the numerical value range of a certain stage may be replaced with the upper limit value or lower limit value of the numerical value range of another stage. With regard to a numerical value range described in the present specification, the upper limit value or lower limit value of the numerical value range may be replaced with a value shown in the Examples.

When the amount of each component in the composition is mentioned in the present specification, in a case where there is a plurality of substances corresponding to each component in the composition, unless particularly stated otherwise, the amount means the total amount of the plurality of substances present in the composition.

According to the present specification, the term “(meth)acrylate” means at least one of “acrylate” and “methacrylate” corresponding thereto, and the same also applies to other similar expressions such as (meth)acrylic acid and (meth)acryloyl. In the present specification, the term “solid content” refers to a non-volatile fraction excluding volatile substances (water, solvents, and the like) included in the photosensitive resin composition, and the solid content also includes components that are liquid, syrup-like, or waxy at room temperature (near 25° C.).

### Photosensitive Resin Composition

A photosensitive resin composition for a permanent resist according to the present embodiment includes (A) an acid-modified vinyl group-containing resin, (B) a photopolymerization initiator, and (C) a photopolymerizable compound, and the photopolymerizable compound includes a photopolymerizable compound having four or more ethylenically unsaturated groups and a photopolymerizable compound having three or fewer ethylenically unsaturated groups. The photosensitive resin composition according to the present embodiment is a negative-type photosensitive resin composition, and a cured film of the photosensitive resin composition can be used as a permanent resist. Each component used in the photosensitive resin composition of the present embodiment will be described in more detail below.

### Component (A): Acid-Modified Vinyl Group-Containing Resin

The photosensitive resin composition according to the present embodiment contains an acid-modified vinyl group-containing resin as a component (A). The acid-modified vinyl group-containing resin is not particularly limited as long as it has a vinyl group, which is a photopolymerizable ethylenically unsaturated bond, and an alkali-soluble acidic group. Examples of the acidic group carried by the acid-modified vinyl group-containing resin include a carboxy group, a sulfo group, and a phenolic hydroxyl group. Among these, from the viewpoint of resolution, a carboxy group is preferred.

Examples of the acid-modified vinyl group-containing resin include an acid-modified epoxy (meth)acrylate. The acid-modified epoxy (meth)acrylate is a resin obtained by acid-modifying epoxy (meth)acrylate, which is a reaction product of an epoxy resin and an organic acid having a vinyl group. As the acid-modified epoxy (meth)acrylate, for example, an addition reaction product produced by adding a saturated or unsaturated polybasic acid anhydride (c) to an esterification product obtained by reacting an epoxy resin (a) with a vinyl group-containing monocarboxylic acid (b), can be used.

Examples of the epoxy resin (a) include a bisphenol novolac type epoxy resin, a novolac type epoxy resin, a bisphenol A type epoxy resin, a bisphenol F type epoxy resin, a triphenolmethane type epoxy resin, a biphenyl type epoxy resin, a naphthalene type epoxy resin, and a dicyclopentadiene type epoxy resin.

Examples of the vinyl group-containing monocarboxylic acid (b) include acrylic acid; acrylic acid derivatives such as dimer of acrylic acid, methacrylic acid, β-furfuryl acrylic acid, β-styryl acrylic acid, cinnamic acid, crotonic acid, and α-cyanocinnamic acid; a semi-ester compound, which is a reaction product between a hydroxyl group-containing (meth)acrylate and a dibasic acid anhydride; and a semi-ester compound, which is a reaction product between a vinyl group-containing monoglycidyl ether or a vinyl group-containing monoglycidyl ester and a dibasic acid anhydride.

Examples of the hydroxyl group-containing (meth)acrylate, vinyl group-containing monoglycidyl ether, and vinyl group-containing monoglycidyl ester include hydroxyethyl acrylate, hydroxyethyl methacrylate, hydroxypropyl acrylate, hydroxypropyl methacrylate, hydroxybutyl acrylate, hydroxybutyl methacrylate, polyethylene glycol monoacrylate, polyethylene glycol monomethacrylate, trimethylolpropane diacrylate, trimethylolpropane dimethacrylate, pentaerythritol triacrylate, pentaerythritol trimethacrylate, dipentaerythritol pentaacrylate, pentaerythritol pentamethacrylate, glycidyl acrylate, and glycidyl methacrylate.

Examples of the dibasic acid anhydride include succinic anhydride, maleic anhydride, tetrahydrophthalic anhydride, phthalic anhydride, methyltetrahydrophthalic anhydride, ethyltetrahydrophthalic anhydride, hexahydrophthalic anhydride, methylhexahydrophthalic anhydride, ethylhexahydrophthalic anhydride, and itaconic anhydride.

Examples of the saturated or unsaturated polybasic acid anhydride (c) include succinic anhydride, maleic anhydride, tetrahydrophthalic anhydride, phthalic anhydride, methyltetrahydrophthalic anhydride, ethyltetrahydrophthalic anhydride, hexahydrophthalic anhydride, methylhexahydrophthalic anhydride, ethylhexahydrophthalic anhydride, and itaconic anhydride. Among these, from the viewpoint of obtaining a photosensitive resin composition capable of forming a pattern with excellent resolution, tetrahydrophthalic anhydride may be used as the polybasic acid anhydride.

The acid value of the component (A) is not particularly limited. From the viewpoint of improving the solubility of unexposed parts in an alkali aqueous solution, the acid value of the component (A) may be 30 mg KOH/g or more, 40 mg KOH/g or more, or 50 mg KOH/g or more. From the viewpoint of improving the electrical characteristics of the cured film, the acid value of the component (A) may be 150 mg KOH/g or less, 120 mg KOH/g or less, or 100 mg KOH/g or less.

The weight average molecular weight (Mw) of the component (A) is not particularly limited. From the viewpoint of improving the close adhesiveness of the cured film, the Mw of the component (A) may be 3000 or more, 4000 or more, or 5000 or more. From the viewpoint of improving the resolution of the photosensitive layer, the Mw of the component (A) may be 30000 or less, 25000 or less, or 18000 or less. The Mw can be measured by a gel permeation chromatography (GPC) method.

The content of the component (A) in the photosensitive resin composition may be 20 to 70% by mass, 25 to 60% by mass, or 30 to 50% by mass, based on the total solid content of the photosensitive resin composition, from the viewpoint of improving the heat resistance, electrical characteristics, and chemical resistance of the permanent resist.

### Component (B): Photopolymerization Initiator

The photopolymerization initiator as a component (B) is not particularly limited as long as it can polymerize the component (A). Regarding the component (B), one kind thereof may be used alone, or two or more kinds thereof may be used in combination.

Examples of the component (B) include benzoin compounds such as benzoin, benzoin methyl ether, and benzoin isopropyl ether; acetophenone compounds such as acetophenone, 2,2-dimethoxy-2-phenylacetophenone, 2,2-diethoxy-2-phenylacetophenone, 1,1-dichloroacetophenone, 1-hydroxycyclohexyl phenyl ketone, 2-benzyl-2-dimethylamino-1-(4-morpholinophenyl)-butanone-1,2-methyl-[4-(methylthio)phenyl]-2-morpholino-1-propane, and N,N-dimethylaminoacetophenone; anthraquinone compounds such as 2-methylanthraquinone, 2-ethylanthraquinone, 2-tert-butylanthraquinone, 1-chloroanthraquinone, 2-amylanthraquinone, and 2-aminoanthraquinone; thioxanthone compounds such as 2,4-dimethylthioxanthone, 2,4-diethylthioxanthone, 2-chlorothioxanthone, and 2,4-diisopropylthioxanthone; ketal compounds such as acetophenone dimethyl ketal and benzyl dimethyl ketal; benzophenone compounds such as benzophenone, methylbenzophenone, 4,4′-dichlorobenzophenone, 4,4′-bis(diethylamino)benzophenone, Michler's ketone, and 4-benzoyl-4′-methyldiphenyl sulfide; imidazole compounds such as 2-(o-chlorophenyl)-4,5-diphenylimidazole dimer, 2-(o-chlorophenyl)-4,5-di(m-methoxyphenyl)imidazole dimer, 2-(o-fluorophenyl)-4,5-diphenylimidazole dimer, 2-(o-methoxyphenyl)-4,5-diphenylimidazole dimer, 2-(p-methoxyphenyl)-4,5-diphenylimidazole dimer, 2,4-di(p-methoxyphenyl)-5-phenylimidazole dimer, and 2-(2,4-dimethoxyphenyl)-4,5-diphenylimidazole dimer; acridine compounds such as 9-phenylacridine and 1,7-bis(9,9′-acridinyl)heptane; acylphosphine oxide compounds such as 2,4,6-trimethylbenzoyldiphenylphosphine oxide; oxime ester compounds such as 1,2-octanedione-1-[4-(phenylthio)phenyl]-2-(O-benzoyloxime), 1-[9-ethyl-6-(2-methylbenzoyl)-9H-carbazol-3-yl]ethanone-1-(O-acetyloxime), and 1-phenyl-1,2-propanedione-2-[O-(ethoxycarbonyl)oxime]; and tertiary amine compounds such as N,N-dimethylaminobenzoic acid ethyl ester, N,N-dimethylaminobenzoic acid isoamyl ester, pentyl-4-dimethylaminobenzoate, triethylamine, and triethanolamine.

The content of the component (B) in the photosensitive resin composition is not particularly limited; however, the content may be 0.2 to 15% by mass, 0.5 to 10% by mass, or 1 to 5% by mass, based on the total solid content of the photosensitive resin composition.

### Component (C): Photopolymerizable Compound

The photosensitive resin composition according to the present embodiment can improve the resolution of the photosensitive resin composition by using a photopolymerizable compound having four or more ethylenically unsaturated groups and a photopolymerizable compound having three or fewer ethylenically unsaturated groups in combination as a component (C). The ethylenically unsaturated group is not particularly limited as long as it is a group having photopolymerizable properties. The component (C) is a photopolymerizable compound that does not have an acidic group.

As the component (C) includes a photopolymerizable compound having four or more ethylenically unsaturated groups, the crosslinking density can be increased by photocuring of the photosensitive resin composition, and the heat resistance and electrical insulation properties of the permanent resist can be improved. The photopolymerizable compound having four or more ethylenically unsaturated groups may have 4 to 10, 4 to 8, or 5 to 7 ethylenically unsaturated groups.

Examples of the photopolymerizable compound having four or more ethylenically unsaturated groups include dipentaerythritol hexa(meth)acrylate, dipentaerythritol penta(meth)acrylate, and tetramethylolmethane tetra(meth)acrylate. From the viewpoint of improving the sensitivity of the photosensitive resin composition, it is preferable that the component (C) includes dipentaerythritol hexa(meth)acrylate.

As the component (C) includes a photopolymerizable compound having three or fewer ethylenically unsaturated groups, the resolution of the photosensitive resin composition can be increased. As the photopolymerizable compound having three or fewer ethylenically unsaturated groups, at least one selected from the group consisting of a photopolymerizable compound having one ethylenically unsaturated group, a photopolymerizable compound having two ethylenically unsaturated groups, and a photopolymerizable compound having three ethylenically unsaturated groups, can be used. From the viewpoint of further increasing the resolution of the photosensitive resin composition, it is preferable that the component (C) includes a photopolymerizable compound having one ethylenically unsaturated group. From the viewpoint of increasing the film strength of the permanent resist, it is preferable that the component (C) includes a photopolymerizable compound having two or three ethylenically unsaturated groups.

From the viewpoint of further improving the resolution, the photopolymerizable compound having three or fewer ethylenically unsaturated groups may be at least one selected from the group consisting of a photopolymerizable compound having a dicyclopentadiene skeleton, a photopolymerizable compound having an isocyanate group, a photopolymerizable compound having a blocked isocyanate group, and a photopolymerizable compound having an oxyalkylene group.

Examples of the photopolymerizable compound having one ethylenically unsaturated group include (meth)acrylates having a dicyclopentadiene skeleton, such as dicyclopentanyl methacrylate or dicyclopentanyl acrylate; (meth)acrylates having an isocyanate group, such as 2-isocyanatoethyl methacrylate, 2-isocyanatoethyl acrylate, 2-(2-methacryloyloxyethyloxy)ethyl isocyanate, and 2-(2-acryloyloxyethyloxy)ethyl isocyanate; and (meth)acrylates having a blocked isocyanate group, such as 2-[0-(1′-methylpropylideneamino)carboxyamino]ethyl methacrylate and 2-[(3,5-dimethylpyrazolyl)carbonylamino]ethyl methacrylate.

Examples of the photopolymerizable compound having two ethylenically unsaturated groups include alkylene di(meth)acrylates such as ethylene glycol di(meth)acrylate, propylene glycol di(meth)acrylate, tetraethylene glycol di(meth)acrylate, 1,6-hexanediol di(meth)acrylate, 1,9-nonanediol di(meth)acrylate, 1,10-decanediol di(meth)acrylate, and neopentyl glycol di(meth)acrylate; polyalkylene glycol di(meth)acrylates such as polyethylene glycol di(meth)acrylate, polypropylene glycol di(meth)acrylate, and polyethylene-polypropylene glycol di(meth)acrylate; and alkylene oxide-modified di(meth)acrylates such as EO-modified bisphenol A di(meth)acrylate and PO-modified bisphenol A di(meth)acrylate. The term “EO-modified” means having a block structure of an ethylene oxide (EO) group, and the term “PO-modified” means having a block structure of a propylene oxide (PO) group.

Examples of the photopolymerizable compound having three ethylenically unsaturated groups include trimethylolpropane tri(meth)acrylate, dipentaerythritol tri(meth)acrylate, tetramethylolmethane tri(meth)acrylate, EO-modified trimethylolpropane tri(meth)acrylate, PO-modified trimethylolpropane tri(meth)acrylate, and EO-and PO-modified trimethylolpropane tri(meth)acrylate.

The content of the component (C) may be 2 to 30% by mass, 3 to 20% by mass, or 3 to 15% by mass, based on the total solid content of the photosensitive resin composition. When the content of the component (C) is 2% by mass or more, the photosensitivity of the photosensitive resin composition is likely to be improved, and when the content is 30% by mass or less, the heat resistance of the permanent resist is likely to be improved.

From the viewpoint of further increasing the resolution of the photosensitive resin composition, the content of the photopolymerizable compound having three or fewer ethylenically unsaturated groups may be 1% by mass or more, 2% by mass or more, or 3% by mass or more, based on the total solid content of the photosensitive resin composition. From the viewpoint of further improving the film strength of the permanent resist, the content of the photopolymerizable compound having three or fewer ethylenically unsaturated groups may be 20% by mass or less, 15% by mass or less, or 10% by mass or less, based on the total solid content of the photosensitive resin composition.

### Component (D): Inorganic Filler

The photosensitive resin composition according to the present embodiment may further contain an inorganic filler as a component (D). By containing the component (D), the adhesive strength, reliability, and the like of the permanent mask resist can be improved. Regarding the component (D), one kind thereof may be used alone, or two or more kinds thereof may be used in combination.

Examples of the inorganic filler include silica, alumina, titania, tantalum oxide, zirconia, silicon nitride, barium titanate, barium carbonate, magnesium carbonate, aluminum hydroxide, magnesium hydroxide, lead titanate, lead zirconate titanate, lead lanthanum zirconate titanate, gallium oxide, spinel, mullite, cordierite, talc, aluminum titanate, yttria-containing zirconia, barium silicate, boron nitride, calcium carbonate, barium sulfate, calcium sulfate, zinc oxide, magnesium titanate, hydrotalcite, mica, calcined kaolin, and carbon.

From the viewpoint of improving the heat resistance of the permanent resist, the component (D) may include silica, and from the viewpoint of improving the heat resistance and adhesive strength of the permanent resist, the component (D) may include barium sulfate. From the viewpoint of improving the dispersibility of the inorganic filler, an inorganic filler whose surface has been treated in advance with alumina or an organosilane compound may be used.

The average particle size of the inorganic filler may be 0.01 μm or more, 0.1 μm or more, 0.2 μm or more, or 0.3 μm or more, and may be 5.0 μm or less, 3.0 μm or less, 2.0 μm or less, or 1.5 μm or less.

The content of the component (D) may be 5 to 70% by mass, 6 to 60% by mass, or 10 to 50% by mass, based on the total solid content of the photosensitive resin composition. When the content of the component (D) is in the above-described range, low coefficient of thermal expansion, heat resistance, film strength, and the like can be further improved.

### Component (E): Thermosetting Resin

The photosensitive resin composition according to the present embodiment may further contain a thermosetting resin as a component (E). By using the component (E), the heat resistance, adhesiveness, chemical resistance, and the like of a cured film (permanent resist) formed from the photosensitive resin composition can be improved. Regarding the component (E), one kind thereof may be used alone, or two or more kinds thereof may be used in combination.

Examples of the component (E) include an epoxy resin, a phenol resin, an unsaturated imide resin, a cyanate resin, an isocyanate resin, a benzoxazine resin, an oxetane resin, an amino resin, an unsaturated polyester resin, an allyl resin, a dicyclopentadiene resin, a silicone resin, a triazine resin, and a melamine resin.

Examples of the epoxy resin include a bisphenol A type epoxy resin, a bisphenol F type epoxy resin, a hydrogenated bisphenol A type epoxy resin, a brominated bisphenol A type epoxy resin, a bisphenol S type epoxy resin, a novolac type epoxy resin, a biphenyl type epoxy resin, a naphthalene type epoxy resin, a dicyclopentadiene type epoxy resin, a hydantoin type epoxy resin, triglycidyl isocyanurate, and bixylenol type epoxy resin.

The content of the component (E) may be 2 to 30% by mass, 5 to 25% by mass, or 8 to 20% by mass, based on the total solid content of the photosensitive resin composition. When the content of the component (E) is in the above-described range, the heat resistance of the formed cured film can be further improved while maintaining favorable developing properties.

### Component (F): Pigment

The photosensitive resin composition of the present embodiment may further contain a pigment as a component (F), from the viewpoint of improving the identifiability or the appearance of the production apparatus. As the component (F), a colorant developing a desired color when hiding wiring or the like, can be used. Examples of the component (F) include phthalocyanine blue, phthalocyanine green, iodine green, diazo yellow, crystal violet, titanium oxide, carbon black, and naphthalene black.

The content of the component (F) may be 0.1 to 10% by mass, 0.5 to 8% by mass, or 1 to 5% by mass, based on the total solid content in the photosensitive resin composition, from the viewpoint of hiding wiring more effectively.

### Component (G): Elastomer

The photosensitive resin composition according to the present embodiment may further contain an elastomer as a component (G). By containing the component (G), decrease in the flexibility and adhesive strength caused by distortion (internal stress) inside the resin due to curing shrinkage of the component (A) can be suppressed.

Examples of the component (G) include a styrene-based elastomer, an olefin-based elastomer, a urethane-based elastomer, a polyester-based elastomer, a polyamide-based elastomer, an acrylic elastomer, and a silicone-based elastomer. Each of these elastomers is composed of a hard segment component that contributes to heat resistance and strength and a soft segment component that contributes to pliability and toughness.

Examples of the styrene-based elastomer include a styrene-butadiene-styrene block copolymer, a styrene-isoprene-styrene block copolymer, a styrene-ethylene-butylene-styrene block copolymer, and a styrene-ethylene-propylene-styrene block copolymer. As the components constituting the styrene-based elastomers, in addition to styrene, styrene derivatives such as α-methylstyrene, 3-methylstyrene, 4-propylstyrene, and 4-cyclohexylstyrene can be used.

Examples of the olefin-based elastomer include an ethylene-propylene copolymer, an ethylene-α-olefin copolymer, an ethylene-α-olefin-non-conjugated diene copolymer, a propylene-α-olefin copolymer, a butene-α-olefin copolymer, an ethylene-propylene-diene copolymer, copolymers of α-olefins with non-conjugated dienes such as dicyclopentadiene, 1,4-hexadiene, cyclooctadiene, methylene norbornene, ethylidene norbornene, butadiene, and isoprene, and a carboxylic acid-modified butadiene-acrylonitrile copolymer.

As the urethane-based elastomer, a compound composed of a hard segment formed of a low-molecular weight (short-chain) diol and a diisocyanate, and a soft segment formed of a high-molecular weight (long-chain) diol and a diisocyanate, can be used.

Examples of the short-chain diol include ethylene glycol, propylene glycol, 1,4-butanediol, and bisphenol A. The number average molecular weight of the short-chain diol is preferably 48 to 500.

Examples of the long-chain diol include polypropylene glycol, polytetramethylene oxide, poly(1,4-butylene adipate), poly(ethylene-1,4-butylene adipate), polycaprolactone, poly(1,6-hexylene carbonate), and poly(1,6-hexylene neopentylene adipate). The number average molecular weight of the long-chain diol is preferably 500 to 10000.

As the polyester-based elastomer, a compound obtained by polycondensing a dicarboxylic acid or a derivative thereof and a diol compound or a derivative thereof, can be used.

Examples of the dicarboxylic acid include aromatic dicarboxylic acids such as terephthalic acid, isophthalic acid, and naphthalenedicarboxylic acid; aliphatic dicarboxylic acids having 2 to 20 carbon atoms, such as adipic acid, sebacic acid, and dodecanedicarboxylic acid; and alicyclic dicarboxylic acids such as cyclohexanedicarboxylic acid. Regarding the dicarboxylic acid, one kind thereof can be used alone, or two or more kinds thereof can be used in combination.

Examples of the diol compound include aliphatic diols such as ethylene glycol, 1,3-propanediol, 1,4-butanediol, 1,6-hexanediol, and 1,10-decanediol; alicyclic diols such as 1,4-cyclohexanediol; and aromatic diols such as bisphenol A, bis-(4-hydroxyphenyl)methane, bis-(4-hydroxy-3-methylphenyl)propane, and resorcin.

As the polyester-based elastomer, a multiblock copolymer composed of an aromatic polyester (for example, polybutylene terephthalate) as a hard segment component, and an aliphatic polyester (for example, polytetramethylene glycol) as a soft segment component, can be used. There are polyester-based elastomers of various grades depending on the types of the hard segment and the soft segment, the ratio, and the difference in molecular weight.

Polyamide-based elastomers are roughly classified into two types, namely, a polyether block amide type and a polyether ester block amide type, which use a polyamide as a hard segment and a polyether or a polyester as a soft segment. Examples of the polyamide include polyamide-6, polyamide-11, and polyamide-12. Examples of the polyether include polyoxyethylene glycol, polyoxypropylene glycol, and polytetramethylene glycol.

As the acrylic elastomer, a compound including a constituent unit based on a (meth)acrylic acid ester as a main component can be used. Examples of the (meth)acrylic acid ester include methyl (meth)acrylate, ethyl (meth)acrylate, butyl (meth)acrylate, methoxyethyl (meth)acrylate, and ethoxyethyl (meth)acrylate. The acrylic elastomer may be a compound obtained by copolymerizing a (meth)acrylic acid ester and acrylonitrile or may be a compound obtained by further copolymerizing the resulting compound with a monomer having a functional group that serves as a crosslinking point. Examples of the monomer having a functional group include glycidyl methacrylate and allyl glycidyl ether.

Examples of the acrylic elastomer include an acrylonitrile-butyl acrylate copolymer, an acrylonitrile-butyl acrylate-ethyl acrylate copolymer, a methyl methacrylate-butyl acrylate-methacrylic acid copolymer, and an acrylonitrile-butyl acrylate-glycidyl methacrylate copolymer. As the acrylic elastomer, an acrylonitrile-butyl acrylate-glycidyl methacrylate copolymer or a methyl methacrylate-butyl acrylate-methacrylic acid copolymer is preferred, and a methyl methacrylate-butyl acrylate-methacrylic acid copolymer is more preferred.

A silicone-based elastomer is a compound containing an organopolysiloxane as a main component. Examples of the organopolysiloxane include polydimethylsiloxane, polymethylphenylsiloxane, and polydiphenylsiloxane. The silicone-based elastomer may be a compound obtained by modifying a portion of an organopolysiloxane with a vinyl group, an alkoxy group, or the like.

The component (G) may include a carboxylic acid-modified butadiene-acrylonitrile copolymer or a polyester-based elastomer having a hydroxyl group, from the viewpoint of improving the close adhesiveness of the cured film.

The content of the component (G) may be 2 to 50 parts by mass, 4 to 45 parts by mass, 6 to 40 parts by mass, or 10 to 35 parts by mass, with respect to 100 parts by mass of the component (A). When the content of the component (G) is in the above-described range, the elastic modulus in a high-temperature region of the cured film is lowered, and unexposed parts are more easily eluted by a developing solution.

### Other Components

The photosensitive resin composition according to the present embodiment may further contain various additives as necessary. Examples of the additives include polymerization inhibitors such as hydroquinone, methylhydroquinone, hydroquinone monomethyl ether, catechol, and pyrogallol; thickeners such as Bentone and montmorillonite; silicone-based, fluorine-based, and vinyl resin-based antifoaming agents; silane coupling agents; and flame retardants such as a brominated epoxy compound, an acid-modified brominated epoxy compound, an antimony compound, a phosphate compound, an aromatic condensed phosphoric acid ester, and a halogen-containing condensed phosphoric acid ester.

### Solvent

As the photosensitive resin composition according to the present embodiment contains a solvent in order to dissolve or disperse each component, application on a substrate can be made easier, and a coating film having a uniform thickness can be formed.

Examples of the solvent include ketones such as methyl ethyl ketone and cyclohexanone; aromatic hydrocarbons such as toluene, xylene, and tetramethylbenzene; glycol ethers such as methyl cellosolve, butyl cellosolve, methyl carbitol, butyl carbitol, propylene glycol monomethyl ether, dipropylene glycol monoethyl ether, dipropylene glycol diethyl ether, and triethylene glycol monoethyl ether; esters such as ethyl acetate, butyl acetate, butyl cellosolve acetate, and carbitol acetate; aliphatic hydrocarbons such as octane and decane; and petroleum-based solvents such as petroleum ether, petroleum naphtha, hydrogenated petroleum naphtha, and solvent naphtha. Regarding the solvent, one kind thereof may be used alone, or two or more kinds thereof may be used in combination.

The blending amount of the solvent is not particularly limited; however, the proportion of the solvent in the photosensitive resin composition may be 10 to 50% by mass, 20 to 40% by mass, or 25 to 35% by mass.

The photosensitive resin composition of the present embodiment can be prepared by uniformly mixing each of the above-mentioned components with a roll mill, a bead mill, or the like.

### Photosensitive Element

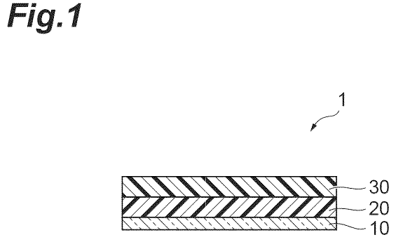

The photosensitive element according to the present embodiment includes: a support film; and a photosensitive layer including the above-mentioned photosensitive resin composition. FIG. 1 is a cross-sectional view schematically illustrating a photosensitive element according to the present embodiment. As shown in FIG. 1, the photosensitive element 1 includes a support film 10 and a photosensitive layer 20 formed on the support film 10.

The photosensitive element 1 can be produced by applying the photosensitive resin composition according to the present embodiment on a support film 10 by a known method such as reverse roll coating, gravure roll coating, comma coating, or curtain coating, and then drying the coating film to form a photosensitive layer 20.

Examples of the support film include polyester films of polyethylene terephthalate, polybutylene terephthalate, and the like, and polyolefin films of polypropylene, polyethylene, and the like. The thickness of the support film may be, for example, 5 to 100 μm. The thickness of the photosensitive layer may be, for example, 5 to 50 μm, 5 to 40 μm, or 10 to 30 μm. The surface roughness of the support film is not particularly limited; however, the arithmetic mean roughness (Ra) may be 1000 nm or less, 500 nm or less, or 250 nm or less.

For the drying of the coating film, hot air drying, or drying using far-infrared radiation or near-infrared radiation can be used. The drying temperature may be 60 to 120° C., 70 to 110° C., or 80 to 100° C. The drying time may be 1 to 60 minutes, 2 to 30 minutes, or 5 to 20 minutes.

On the photosensitive layer 20, a protective film 30 covering the photosensitive layer 20 may be further included. The photosensitive element 1 can have the protective film 30 laminated on a surface of the photosensitive layer 20, the surface being on the opposite side of the surface in contact with the support film 10. As the protective film 30, for example, a polymer film of polyethylene, polypropylene, or the like may be used.

### Printed Wiring Board

A printed wiring board according to the present embodiment includes a permanent resist including a cured product of the photosensitive resin composition according to the present embodiment.

A method for producing a printed wiring board according to the present embodiment includes a step of forming a photosensitive layer on a substrate by using the above-mentioned photosensitive resin composition or the above-mentioned photosensitive element; a step of subjecting the photosensitive layer to exposure and development to form a resist pattern; and a step of curing the resist pattern to form a permanent resist. Examples of each step will be described below.

First, a substrate such as a copper-clad laminated plate is prepared, and a photosensitive layer is formed on the substrate. The photosensitive layer may be formed by applying a photosensitive resin composition on the substrate and drying the photosensitive resin composition. Examples of the method of applying the photosensitive resin composition include a screen printing method, a spraying method, a roll coating method, a curtain coating method, and an electrostatic coating method. The drying temperature may be 60 to 120° C., 70 to 110° C., or 80 to 100° C. The drying time may be 1 to 7 minutes, 1 to 6 minutes, or 2 to 5 minutes.

The photosensitive layer may also be formed by peeling off a protective film from a photosensitive element and laminating the photosensitive layer on the substrate. Examples of the method of laminating the photosensitive layer include a method of performing thermal lamination using a laminator.

Next, a negative film is brought into contact with the photosensitive layer either directly or through a support film, and then the photosensitive layer is exposed by irradiating with actinic rays. Examples of the actinic rays include electron beam, ultraviolet rays, and X-rays, and preferred are ultraviolet rays. As the light source, a low-pressure mercury lamp, a high-pressure mercury lamp, an ultrahigh-pressure mercury lamp, a halogen lamp, or the like can be used. The exposure amount may be 10 to 2000 mJ/cm², 100 to 1500 mJ/cm², or 300 to 1000 mJ/cm².

After exposure, a resist pattern is formed by removing unexposed parts with a developing solution. Examples of the method for developing include a dipping method and a spraying method. As the developing solution, for example, an alkali aqueous solution of potassium hydroxide, sodium hydroxide, sodium carbonate, potassium carbonate, tetramethylammonium hydroxide, or the like can be used.

A patterned cured film (permanent resist) can be formed by subjecting the resist pattern to at least one of post-exposure and post-heating. The exposure amount for post-exposure may be 100 to 5000 mJ/cm², 500 to 2000 mJ/cm², or 700 to 1500 J/cm². The heating temperature for post-heating may be 100 to 200° C., 120 to 180° C., or 135 to 165° C. The heating time for post-heating may be 5 minutes to 12 hours, 10 minutes to 6 hours, or 30 minutes to 2 hours.

The permanent resist according to the present embodiment can be used as an interlayer insulation layer or a surface protective layer for a semiconductor element. A semiconductor element including an interlayer insulation layer or surface protective layer formed from a cured film of the above-mentioned photosensitive resin composition, and an electronic device including the semiconductor element can be produced. The semiconductor element may be, for example, a memory or a package, both of which have a multilayer wiring structure, a re-wiring structure, or the like. Examples of the electronic device include a mobile phone, a smartphone, a tablet type terminal, a person computer, and a hard disk suspension. By preparing a patterned cured film formed by using the photosensitive resin composition according to the present embodiment, a semiconductor element and an electronic device having excellent reliability can be provided.

### EXAMPLES

The present disclosure will be described in more detail below by way of Examples; however, the present invention is not intended to be limited to these Examples.

### Synthesis Example 1

250 parts by mass of a dicyclopentadiene type epoxy resin (manufactured by Nippon Kayaku Co., Ltd., trade name “XD-1000”), 70 parts by mass of acrylic acid, 0.5 parts by mass of methylhydroquinone, and 120 parts by mass of carbitol acetate were mixed while being stirred at 90° C. The mixed liquid was cooled to 60° C., 2 parts by mass of triphenylphosphine was added thereto, and the mixture was caused to react at 100° C. until the acid value of the solution became 1 mg KOH/g. 98 parts by mass of tetrahydrophthalic anhydride and 850 parts by mass of carbitol acetate were added to the reaction liquid, and the mixture was caused to react for 6 hours by heating to 80° C. Thereafter, the reaction liquid was cooled to room temperature, and a solution of an acid-modified epoxy acrylate resin (A-1) (solid content concentration 65% by mass) as the component (A) was obtained.

### Synthesis Example 2

350 parts by mass of bisphenol F novolac type epoxy resin (manufactured by DIC Corporation, trade name “EXA-7376”), 70 parts by mass of acrylic acid, 0.5 parts by mass of methylhydroquinone, and 120 parts by mass of carbitol acetate were mixed while being stirred at 90° C. The mixed liquid was cooled to 60° C., 2 parts by mass of triphenylphosphine was added thereto, and the mixture was caused to react at 100° C. until the acid value of the solution became 1 mg KOH/g or less. 98 parts by mass of tetrahydrophthalic anhydride and 850 parts by mass of carbitol acetate were added to the reaction liquid, and the mixture was caused to react for 6 hours at 80° C. Thereafter, the reaction liquid was cooled to room temperature, and a solution of an acid-modified epoxy acrylate (A-2) (solid content concentration: 73% by mass) as the component (A) was obtained.

The following materials were prepared as components (B) to (G).
B-1: 2-Methyl-[4-(methylthio)phenyl]-2-morpholino-1-propane (manufactured by IGM Resins B.V., trade name “Omirad 907”)
B-2: 2,4-Diethylthioxanthone (manufactured by Nippon Kayaku Co., Ltd., trade name “DETX-S”)
B-3: 4,4′-Bis(diethylamino)benzophenone (EAB)
C-1: Dipentaerythritol hexaacrylate (manufactured by Nippon Kayaku Co., Ltd., trade name “DPHA”)
C-2: Dicyclopentanyl acrylate (manufactured by Showa Denko Materials Co., Ltd., trade name “FA-513AS”)
C-3: Dicyclopentanyl methacrylate (manufactured by Showa Denko Materials Co., Ltd., trade name “FA-513M”)
C-4: 2-Isocyanatoethyl methacrylate (manufactured by Showa Denko K.K., trade name “KARENZ MOI”)
C-5: 2-[0-(1′-methylpropylideneamino)carboxyamino]ethyl methacrylate (manufactured by Showa Denko K.K., trade name “KARENZ MOI-BM”)
C-6: (PO)(EO)(PO)-modified dimethacrylate (manufactured by Showa Denko Materials Co., Ltd., trade name “FA-024M”)
C-7: Trimethylolpropane trimethacrylate (manufactured by SHIN-NAKAMURA CHEMICAL Co., Ltd., trade name “TMPT”)
D-1: Silica (average particle size 0.5 μm)
E-1: Bisphenol novolac type epoxy resin (manufactured by Nippon Kayaku Co., Ltd., trade name “RE-306”)
E-2: Biphenyl type epoxy resin (manufactured by Mitsubishi Chemical Corporation, trade name “YX4000”)
F-1: Phthalocyanine green (manufactured by SANYO COLOR WORKS, Ltd.)

### Photosensitive Resin Composition

Each component was blended in the blending amount (parts by mass, solid content equivalent) shown in Table 1, and the mixture was kneaded with a three-roll mill. Thereafter, carbitol acetate was added such that the solid content concentration was 60% by mass, and a photosensitive resin composition was prepared.

### Photosensitive Element

A polyethylene terephthalate film (manufactured by TEIJIN LIMITED, trade name “G2-16”) having a thickness of 16 μm was prepared as a support film. A photosensitive resin composition was applied on the support film such that the thickness after drying was 10 μm, and the photosensitive resin composition was dried at 75° C. for 30 minutes using a hot air convection type dryer to form a photosensitive layer. Next, a polyethylene film (manufactured by TAMAPOLY CO., LTD., trade name “NF-15”) was stuck as a protective film onto a surface of the photosensitive layer, the surface being on the opposite side of the side in contact with the support film, and a photosensitive element was obtained.

### Resolution

A copper-clad laminated substrate (manufactured by Showa Denko Materials Co., Ltd., trade name “MCL-E-67”) having a thickness of 0.6 mm was prepared. While peeling and removing a protective film from the photosensitive element, a photosensitive layer was laminated on the copper-clad laminated substrate by using a press type vacuum laminator (manufactured by Meiki Co., Ltd., trade name “MVLP-500”) at a pressing pressure of 0.4 MPa, a press hot plate temperature of 80° C., a vacuum drawing time of 25 seconds, and a lamination press time of 25 seconds, and an air pressure of 4 kPa or less, to obtain a laminated body. Next, the photosensitive layer was exposed through a negative mask having a via pattern of a predetermined size, by using an i-line exposure apparatus (manufactured by Ushio Inc., “UX-2240SM-XJ-01”) at an exposure amount in the range of 100 to 1000 mJ/cm² while changing the exposure amount by 50 mJ/cm² at a time. Thereafter, spray development was performed by using a 1% by mass aqueous solution of sodium carbonate for a time period equivalent to twice the shortest development time (shortest time for removing unexposed parts of the photosensitive layer) at 30° C. and at a pressure of 1.765×10⁵ Pa, and unexposed parts were dissolved and developed. Next, the resultant was exposed at an exposure amount of 2000 mJ/cm² by using an ultraviolet exposure apparatus and then was heated at 160° C. for 1 hour to produce a test piece having a cured film provided with a via pattern of a predetermined size on a copper-clad laminated substrate. The test piece was observed by using a metallurgical microscope and was evaluated according to the following criteria.
A: The minimum diameter of the diameters of mask openings was 20 μm or less.
B: The minimum diameter of the diameters of mask openings was more than 20 μm and 25 μm or less.
C: The minimum diameter of the diameters of mask openings was more than 25 μm.

TABLE 1

| | | | | | | | | Comparative | |
|---|---|---|---|---|---|---|---|---|---|
| | | Example | | | | | | Example | |
| | | 1 | 2 | 3 | 4 | 5 | 6 | 1 | 2 |
| (A) | A-1 | 34.12 | 34.12 | 23.9 | 23.9 | 23.9 | 23.9 | 34.12 | 23.9 |
| | A-2 | — | — | 10.7 | 10.7 | 10.7 | 10.7 | — | 10.7 |
| (B) | B-1 | 0.07 | 0.07 | 0.07 | 0.07 | 0.07 | 0.07 | 0.07 | 0.07 |
| | B-2 | 0.05 | 0.05 | 0.05 | 0.05 | 0.05 | 0.05 | 0.05 | 0.05 |
| | B-3 | 0.08 | 0.08 | 0.08 | 0.08 | 0.08 | 0.08 | 0.08 | 0.08 |
| (C) | C-1 | 4.25 | 4.25 | 4.25 | 4.25 | 4.25 | 4.25 | 4.25 | 4.25 |
| | C-2 | 4.86 | — | — | — | — | — | — | — |
| | C-3 | — | 4.86 | 4.86 | 4.86 | — | — | — | — |
| | C-4 | — | — | 0.87 | — | — | — | — | — |
| | C-5 | — | — | — | 0.87 | — | — | — | — |
| | C-6 | — | — | — | — | 4.86 | — | — | — |
| | C-7 | — | — | — | — | — | 4.86 | — | — |
| (D) | D-1 | 38.25 | 38.25 | 38.25 | 38.25 | 38.25 | 38.25 | 38.25 | 38.25 |
| (E) | E-1 | 2.23 | 2.23 | 2.23 | 2.23 | 2.23 | 2.23 | 2.23 | 2.23 |
| | E-2 | 7.54 | 7.54 | 7.54 | 7.54 | 7.54 | 7.54 | 7.54 | 7.54 |
| (F) | F-1 | 1.18 | 1.18 | 1.18 | 1.18 | 1.18 | 1.18 | 1.18 | 1.18 |

| | | | | | | | | |
|---|---|---|---|---|---|---|---|---|
| Resolution | A | A | A | A | A | A | C | B |

### REFERENCE SIGNS LIST

1: photosensitive element, 10: support film, 20: photosensitive layer, 30: protective film.

1. A photosensitive resin composition for a permanent resist, the photosensitive resin composition comprising:
(A) an acid-modified vinyl group-containing resin;
(B) a photopolymerization initiator; and
(C) a photopolymerizable compound,
wherein the photopolymerizable compound includes a photopolymerizable compound having four or more ethylenically unsaturated groups and a photopolymerizable compound having three or fewer ethylenically unsaturated groups.

2. The photosensitive resin composition according to claim 1, wherein the photopolymerizable compound having three or fewer ethylenically unsaturated groups has a dicyclopentadiene skeleton.

3. The photosensitive resin composition according to claim 1, wherein the photopolymerizable compound having three or fewer ethylenically unsaturated groups has an isocyanate group, a blocked isocyanate group, or an oxyalkylene group.

4. The photosensitive resin composition according to claim 1, further comprising (D) an inorganic filler.

5. The photosensitive resin composition according to claim 1, further comprising (E) a thermosetting resin.

6. The photosensitive resin composition according to claim 1, further comprising (F) a pigment.

7. A photosensitive element comprising a support film and a photosensitive layer formed on the support film,
wherein the photosensitive layer includes the photosensitive resin composition according to claim 1.

8. A printed wiring board comprising a permanent resist including a cured product of the photosensitive resin composition according to claim 1.

9. A method for producing a printed wiring board, the method comprising:
a step of forming a photosensitive layer on a substrate by using the photosensitive resin composition according to claim 1;
a step of subjecting the photosensitive layer to exposure and development to form a resist pattern; and
a step of curing the resist pattern to form a permanent resist.

10. A method for producing a printed wiring board, the method comprising:
a step of forming a photosensitive layer on a substrate by using the photosensitive element according to claim 7;
a step of subjecting the photosensitive layer to exposure and development to form a resist pattern; and
a step of curing the resist pattern to form a permanent resist.
